(19) United States
(12) Patent Application Publication
(10) Pub. No.: US 2026/0148781 A1
(43) Pub. Date: May 28, 2026

(54) NON-VOLATILE MEMORY DEVICE INCLUDING MULTIPLE PAGE BUFFER CIRCUITS, METHOD OF OPERATING THE SAME, AND STORAGE DEVICE INCLUDING THE SAME

(71) Applicant: Samsung Electronics Co., Ltd., Suwon-si (KR)

(72) Inventors: Deokgon Seo, Suwon-si (KR); Woosul Shin, Suwon-si (KR); Hyun Jun Yoon, Suwon-si (KR)

(21) Appl. No.: 19/382,810

(22) Filed: Nov. 7, 2025

(30) Foreign Application Priority Data
Nov. 26, 2024 (KR) 10-2024-0171270

(51) Int. Cl. G11C 16/34; G11C 16/10; G11C 16/04

(52) U.S. Cl. CPC G11C 16/3459; G11C 16/10; G11C 16/0483

(57) ABSTRACT

Disclosed is a non-volatile memory device including a first memory plane circuit, a second memory plane circuit, a first page buffer circuit connected to the first memory plane circuit, a second page buffer circuit connected to the second memory plane circuit, and a control logic circuit. During a first sequence, the control logic circuit provides first latch control signals to the first page buffer circuit to receive first verification information and provides second latch control signals to the second page buffer circuit to receive second verification information. During a second sequence following the first sequence, the control logic circuit enables the first page buffer circuit to perform a second program operation based on the first verification information indicating a pass state and enables the second page buffer circuit to perform the first program operation based on the second verification information indicating a fail state.

### CROSS-REFERENCE TO RELATED APPLICATIONS

This application claims priority under 35 U.S.C. § 119 to Korean Patent Application No. 10-2024-0171270 filed on November 26, 2024, in the Korean Intellectual Property Office, the disclosures of which are incorporated by reference herein in their entireties.

### BACKGROUND

Embodiments of the present disclosure described herein relate to a non-volatile memory device, and more particularly, relate to a non-volatile memory device including a plurality of page buffer circuits, an operating method thereof, and a storage device including the same.

A storage device refers to a device, which stores data under control of a host device, such as a computer, a smartphone, or a smart pad. The storage device includes a device, which uses a semiconductor memory, such as a solid state drive (SSD) or a memory card, in addition to a magnetic disk-based storage device such as a hard disk drive (HDD). In particular, the semiconductor memory may use a non-volatile memory, which is a memory technology capable of maintained data even at power-off.

The non-volatile memory includes a read only memory (ROM), a programmable ROM (PROM), an electrically programmable ROM (EPROM), an electrically erasable and programmable ROM (EEPROM), a flash memory, a phase-change random access memory (PRAM), a magnetic RAM (MRAM), a resistive RAM (RRAM), a ferroelectric RAM (FRAM), etc.

With the development of semiconductor manufacturing technologies, higher integration of the storage device is occurring, and thus, the capacity of the storage device is quickly increasing. The higher integration helps reduce manufacturing costs for the storage device. In contrast, the higher integration causes new issues. In particular, because the higher integration makes the size of the storage device decrease and the structure of the storage device becomes complicated, various issues which do not exist previously are caused.

In addition, it is important to improve the power efficiency of the storage device. Various technical approaches are being attempted to improve power efficiency, and as such, efforts to minimize energy consumption while maintaining high performance are continuing.

### SUMMARY

Embodiments of the present disclosure provide a non-volatile memory device including a plurality of page buffer circuits, an operating method thereof, and a storage device including the same.

According to some embodiments, a non-volatile memory device includes a first memory plane circuit, a second memory plane circuit, a first page buffer circuit connected to the first memory plane circuit through first bit lines, a second page buffer circuit connected to the second memory plane circuit through second bit lines, and a control logic circuit. During a first sequence, the control logic circuit provides first latch control signals to the first page buffer circuit to verify a first program operation of the first memory plane circuit and receive first verification information. During the first sequence, the control logic circuit provides second latch control signals to the second page buffer circuit to verify the first program operation of the second memory plane circuit and receive second verification information. During a second sequence following the first sequence, the control logic circuit provides third latch control signals to the first page buffer circuit to perform a second program operation based on the first verification information indicating a pass state. During the second sequence, the control logic circuit provides fourth latch control signals to the second page buffer circuit to perform the first program operation based on the second verification information indicating a fail state.

According to some embodiments, an operating method of a non-volatile memory device which includes a first page buffer circuit connected to a first memory plane circuit, a second page buffer circuit connected to a second memory plane circuit, and a control logic circuit includes providing, by the control logic circuit, first latch control signals to the first page buffer circuit to verify a first program operation of the first memory plane circuit and receiving first verification information during a first sequence, providing, by the control logic circuit, second latch control signals to the second page buffer circuit to verify the first program operation of the second memory plane circuit and receiving second verification information during the first sequence, providing, by the control logic circuit, third latch control signals to the first page buffer circuit to perform a second program operation based on the first verification information indicating a pass state during a second sequence following the first sequence, and providing, by the control logic circuit, fourth latch control signals to the second page buffer circuit to perform the first program operation based on the second verification information indicating a fail state during the second sequence.

According to some embodiments, a storage device includes a non-volatile memory device, and a storage controller that controls the non-volatile memory device. The non-volatile memory device includes a first memory plane circuit, a second memory plane circuit, a first page buffer circuit connected to the first memory plane circuit through first bit lines, a second page buffer circuit connected to the second memory plane circuit through second bit lines, and a control logic circuit. During a first sequence, the control logic circuit provides first latch control signals to the first page buffer circuit to verify a first program operation of the first memory plane circuit and receive first verification information. During the first sequence, the control logic circuit provides second latch control signals to the second page buffer circuit to verify the first program operation of the second memory plane circuit and receive second verification information. During a second sequence following the first sequence, the control logic circuit provides third latch control signals to the first page buffer circuit to perform a second program operation based on the first verification information indicating a pass state. During the second sequence, the control logic circuit provides fourth latch control signals to the second page buffer circuit to perform the first program operation based on the second verification information indicating a fail state.

### BRIEF DESCRIPTION OF THE FIGURES

The above and other objects and features of the present disclosure will become apparent by describing in detail embodiments thereof with reference to the accompanying drawings.

FIG. 1 is a block diagram of an electronic device according to some embodiments of the present disclosure.

FIG. 2 is a block diagram of a non-volatile memory device according to some embodiments of the present disclosure.

FIG. 3 is a distribution diagram for describing a program operation of a non-volatile memory device according to some embodiments of the present disclosure.

FIG. 4 is a diagram describing a page buffer circuit according to some embodiments of the present disclosure.

FIG. 5 is a block diagram of a non-volatile memory device according to some embodiments of the present disclosure.

FIG. 6 is a diagram describing a conventional latch controller.

FIG. 7 is a diagram describing a latch controller according to some embodiments of the present disclosure.

FIG. 8 is a timing diagram describing latch control signals which a conventional control logic circuit may generate.

FIG. 9 is a timing diagram describing latch control signals which a control logic circuit according to some embodiments of the present disclosure may generate.

FIG. 10 is a timing diagram describing latch control signals which a control logic circuit according to some embodiments of the present disclosure may generate.

FIG. 11 is a flowchart describing an operating method of a non-volatile memory device according to some embodiments of the present disclosure.

### DETAILED DESCRIPTION

Below, embodiments of the present disclosure will be described in detail and clearly to such an extent that one skilled in the art carries out embodiments of the present disclosure easily.

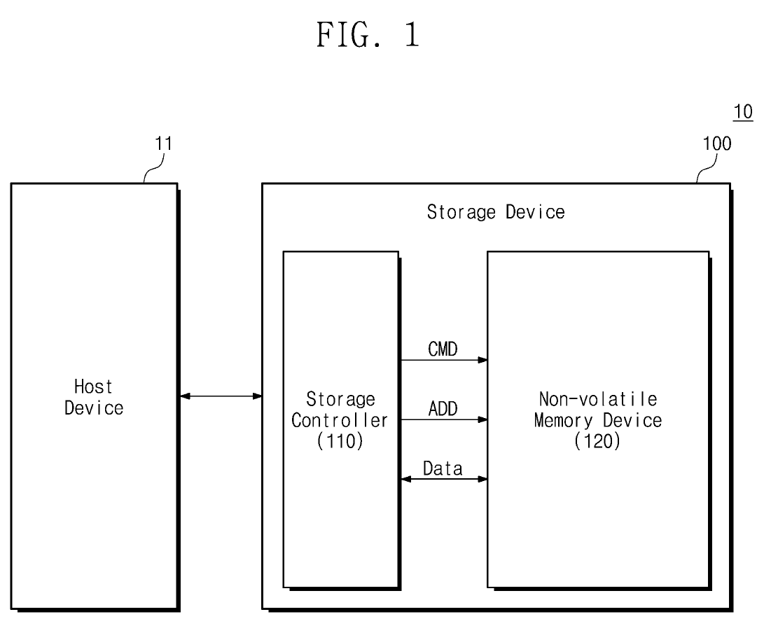

FIG. 1 is a block diagram of an electronic device according to some embodiments of the present disclosure. Referring to FIG. 1, an electronic device 10 may include a host device 11 and a storage device 100. The electronic device 10 may be a computing system, which is configured to process a variety of information, such as a personal computer (PC), a notebook, a laptop, a server, a workstation, a tablet PC, a smartphone, a digital camera, and a black box.

The host device 11 may control all operations of the electronic device 10. For example, the host device 11 may write data into the storage device 100 or may read data stored in the storage device 100. The host device 11 may provide a command and an address to the storage device 100 to read the data stored in the storage device 100.

The host device 11 may communicate with the storage device 100 through a host interface. The host interface may include at least one of various interfaces such as an ATA (Advanced Technology Attachment) interface, an SATA (Serial ATA) interface, an e-SATA (external SATA) interface, an SCSI (Small Computer Small Interface) interface, an SAS (Serial Attached SCSI) interface, a PCI (Peripheral Component Interconnection) interface, a PCIe (PCI express) interface, an NVMe (NVM express) interface, an IEEE 1394 interface, an USB (Universal Serial Bus) interface, an SD (Secure Digital) card interface, an MMC (Multi-Media Card) interface, an eMMC (embedded Multi-Media Card) interface, an UFS (Universal Flash Storage) interface, an eUFS (embedded Universal Flash Storage) interface, and/or a CF (Compact Flash) card interface.

The storage device 100 may operate under control of the host device 11. For example, the storage device 100 may receive commands from the host device 11 and may perform a process based on the commands.

The storage device 100 may include a storage controller 110 and a non-volatile memory device 120. The storage controller 110 may receive various requests from the host device 11 for writing data in the non-volatile memory device 120 or reading data “DATA” from the non-volatile memory device 120,.

The storage controller 110 may be configured to control the non-volatile memory device 120. For example, the storage controller 110 may store the data “DATA” in the non-volatile memory device 120 or may read the data “DATA” stored in the non-volatile memory device 120. For example, the storage controller 110 may transmit a command CMD and an address ADD to the non-volatile memory device 120 and may exchange the data “DATA” with the non-volatile memory device 120.

The non-volatile memory device 120 may operate under control of the storage controller 110. For example, in response to signals received from the storage controller 110, the non-volatile memory device 120 may store the received data “DATA” or may output the stored data “DATA”. In some embodiments, the non-volatile memory device 120 may be a NAND flash memory device, but the present disclosure is not limited thereto. For example, the non-volatile memory device 120 may include one of various storage devices, which retain data stored therein even though a power is turned off, such as a phase-change random access memory (PRAM), a magnetic random access memory (MRAM), a resistive random access memory (RRAM), and/or a ferroelectric random access memory (FRAM).

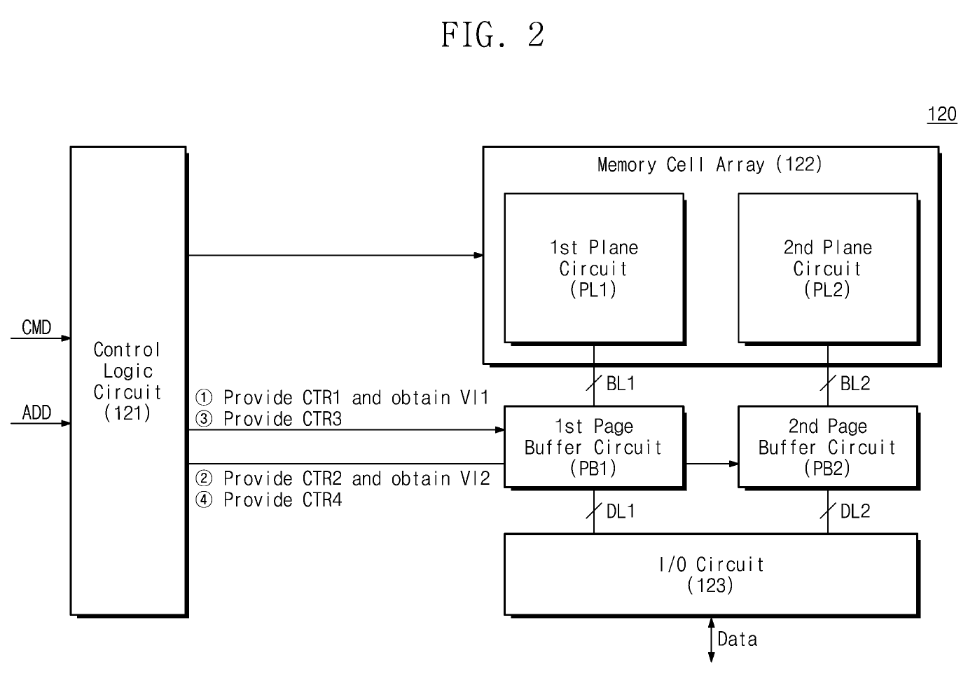

FIG. 2 is a block diagram of a non-volatile memory device according to some embodiments of the present disclosure. Referring to FIG. 2, the non-volatile memory device 120 may include a control logic circuit 121, a memory cell array 122, an input/output circuit 123, a first page buffer circuit PB1, and a second page buffer circuit PB2.

The control logic circuit 121 may control the non-volatile memory device 120 or various components of the non-volatile memory device 120. For example, the control logic circuit 121 may receive the command CMD and the address ADD from the storage controller 110 of FIG. 1 and may control the non-volatile memory device 120 or various components of the non-volatile memory device 120 based on the command CMD and the address ADD. In some embodiments, the control logic circuit 121 may decode the command CMD and the address ADD received from the storage controller 110 of FIG. 1, or may control the non-volatile memory device 120 or various components of the non-volatile memory device 120 based on the decoded command and address.

In some embodiments, the control logic circuit 121 may output various control signals to perform the program operation, the verify operation, or the read operation of the non-volatile memory device 120.

In some embodiments, the control logic circuit 121 may control a row decoding circuit of the memory cell array 122 such that string selection lines, word lines, and ground selection lines of the memory cell array 122 are controlled or driven or voltages are applied to the string selection lines, the word lines, and/or the ground selection lines.

The control logic circuit 121 may control the first page buffer circuit PB1 and the second page buffer circuit PB2. For example, the control logic circuit 121 may individually control the first page buffer circuit PB1 and the second page buffer circuit PB2 within the same sequence or the same time period. In some embodiments, the control logic circuit 121 may individually control the first page buffer circuit PB1 and the second page buffer circuit PB2 to perform different program operations or to verify different program operations. The control logic circuit 121 may reduce power consumption of a page buffer circuit which completes the program operation, by individually controlling the first page buffer circuit PB1 and the second page buffer circuit PB2.

The control logic circuit 121 may provide latch control signals to the first page buffer circuit PB1 and the second page buffer circuit PB2. The latch control signals may be signals for controlling latches of each of the first page buffer circuit PB1 and the second page buffer circuit PB2. For example, to perform the program operation of the memory cell array 122 or to verify the program operation, the control logic circuit 121 may provide the latch control signals (e.g., first, second, third, and fourth latch control signals CTR1, CTR2, CTR3, and CTR4) to the first page buffer circuit PB1 and the second page buffer circuit PB2.

In some embodiments, the control logic circuit 121 may generate the latch control signals to be provided to the first page buffer circuit PB1 and the second page buffer circuit PB2 based on verification information (e.g., first and second verification information VI1 and VI2) obtained from the first page buffer circuit PB1 and the second page buffer circuit PB2. The verification information may indicate whether the program operation performed by plane circuits in the memory cell array 122 has succeeded or failed.

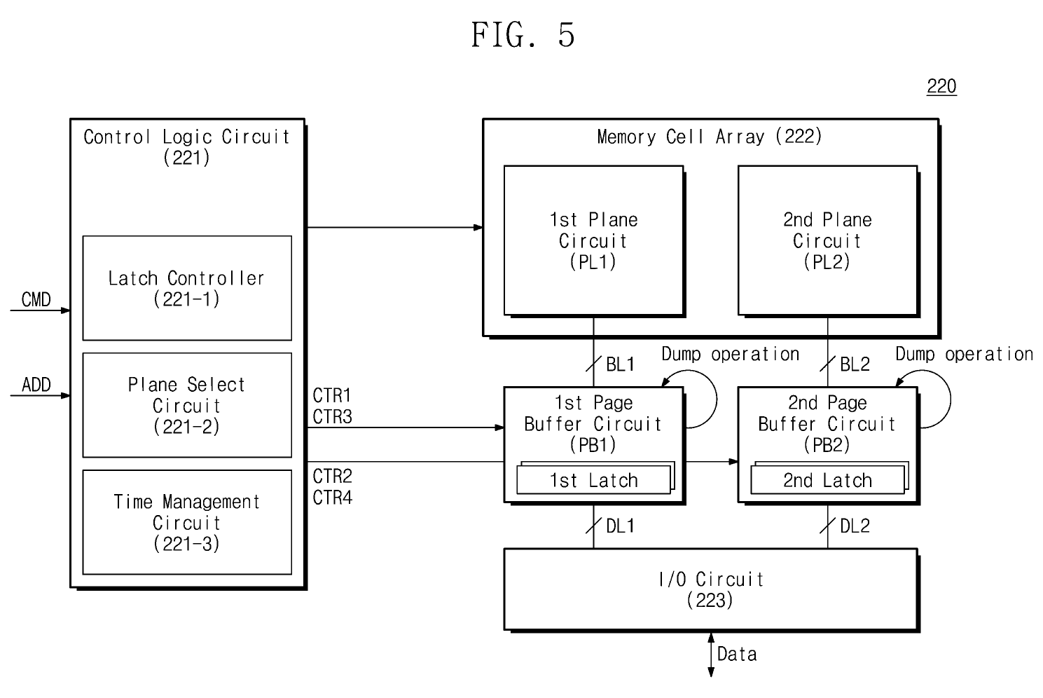

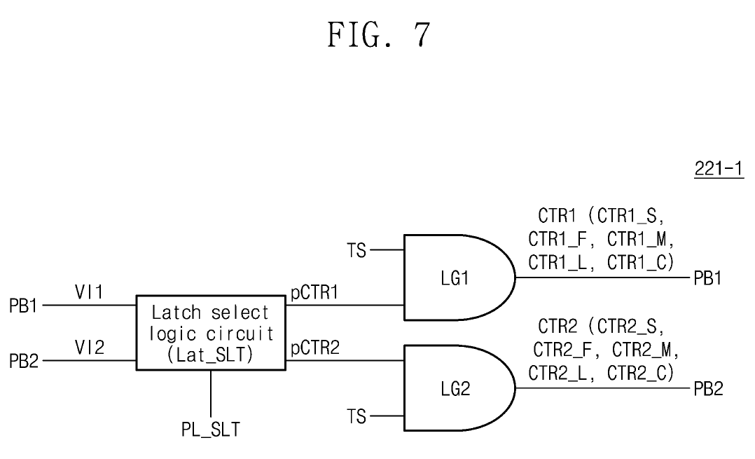

The control logic circuit 121 will be described in detail with reference to FIGS. 5 and 7.

The memory cell array 122 may include a first memory plane circuit PL1 and a second memory plane circuit PL2. Each of the first memory plane circuit PL1 and the second memory plane circuit PL2 may include a plurality of memory blocks. Each of the plurality of memory blocks may include a plurality of memory cells. The plurality of memory blocks of the first memory plane circuit PL1 may be connected to the first page buffer circuit PB1 through first bit lines BL1, and the plurality of memory blocks of the second memory plane circuit PL2 may be connected to the second page buffer circuit PB2 through second bit lines BL2.

The first memory plane circuit PL1 and the second memory plane circuit PL2 are provided only for better understanding of the memory cell array 122 according to the present disclosure and are not intended to limit the scope of the present disclosure. The memory cell array 122 may include more memory plane circuits including the first memory plane circuit PL1 and the second memory plane circuit PL2.

The first page buffer circuit PB1 may be directly connected to the first memory plane circuit PL1 of the memory cell array 122 through the first bit lines BL1, and the second page buffer circuit PB2 may be directly connected to the second memory plane circuit PL2 of the memory cell array 122 through the second bit lines BL2. Also, the first page buffer circuit PB1 may be connected to the I/O circuit 123 through first data lines DL1, and the second page buffer circuit PB2 may be connected to the I/O circuit 123 through second data lines DL2.

The first page buffer circuit PB1 and the second page buffer circuit PB2 are provided only for better understanding of the non-volatile memory device 120 according to the present disclosure and are not intended to limit the scope of the present disclosure. The non-volatile memory device 120 may include more page buffer circuits including the first page buffer circuit PB1 and the second page buffer circuit PB2.

In some embodiments, in the program operation, the first page buffer circuit PB1 may store data to be written in the plurality of memory cells of the first memory plane circuit PL1, and the second page buffer circuit PB2 may store data to be written in the plurality of memory cells of the second memory plane circuit PL2. Based on the stored data, the first page buffer circuit PB1 and the second page buffer circuit PB2 may apply voltages to the first bit lines BL1 and the second bit lines BL2.

The first page buffer circuit PB1 and the second page buffer circuit PB2 may operate under control of the control logic circuit 121. For example, in the program operation of the non-volatile memory device 120, under control of the control logic circuit 121, the first page buffer circuit PB1 and the second page buffer circuit PB2 may control voltages of the first bit lines BL1 and the second bit lines BL2 based on data to be programmed in the first memory plane circuit PL1 and the second memory plane circuit PL2. In the read operation of the non-volatile memory device 120, the first page buffer circuit PB1 and the second page buffer circuit PB2 may sense voltages of the first bit lines BL1 and the second bit lines BL2 and may store read data as sensing results.

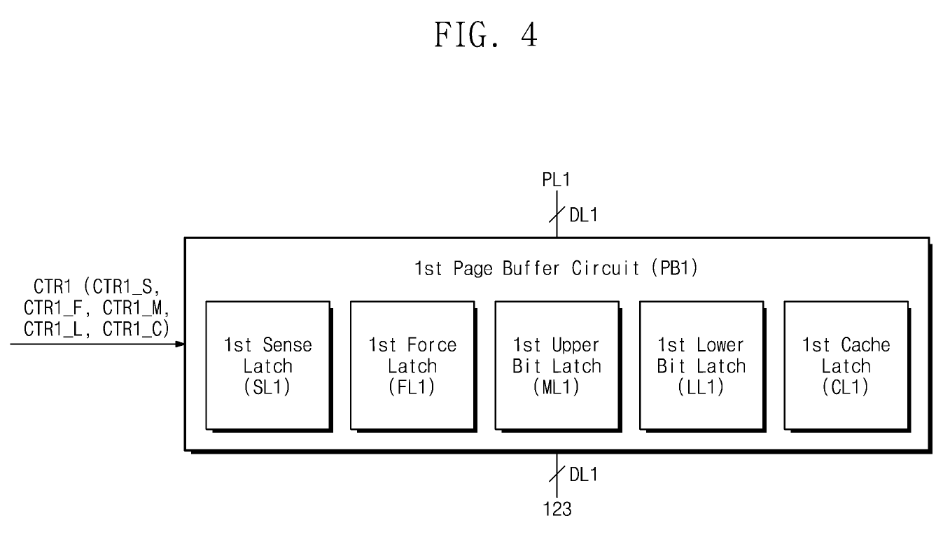

The first page buffer circuit PB1 and the second page buffer circuit PB2 will be described in detail with reference to FIGS. 4 and 5.

The I/O circuit 123 may be connected to the first page buffer circuit PB1 through the first data lines DL1 and may be connected to the second page buffer circuit PB2 through the second data lines DL2. The I/O circuit 123 may receive the data “DATA” from the storage controller 110 of FIG. 1 and may provide the received data “DATA” to the first page buffer circuit PB1 and the second page buffer circuit PB2.

In a first operation ①, the control logic circuit 121 may provide the first latch control signals CTR1 to the first page buffer circuit PB1 and may obtain or receive the first verification information VI1. For example, to verify the program operation of the first memory plane circuit PL1 during a first sequence, the control logic circuit 121 may provide the first latch control signals CTR1 to the first page buffer circuit PB1 and may obtain or receive the first verification information VI1. The first latch control signals CTR1 may be used to control operations which the first memory plane circuit PL1 will perform to verify the first program operation performed in the first memory plane circuit PL1.

The control logic circuit 121 may determine whether the first program operation of the first memory plane circuit PL1 has passed or failed, based on the first verification information VI1 that is obtained or returned from the first page buffer circuit PB1. When the first verification information VI1 indicate that the first program operation has passed, there may be a need to perform the second program operation following the first program operation of the first memory plane circuit PL1. Also, when the first verification information VI1 indicates that the first program operation has failed, there may be a need to again perform the first program operation of the first memory plane circuit PL1.

In a second operation ②, the control logic circuit 121 may provide the second latch control signals CTR2 to the second page buffer circuit PB2 and may obtain or receive the second verification information VI2. For example, to verify the program operation of the second memory plane circuit PL2 during the first sequence, the control logic circuit 121 may provide the second latch control signals CTR2 to the second page buffer circuit PB2 and may obtain or receive the second verification information VI2. That is, during the first sequence in which the control logic circuit 121 provides the first latch control signals CTR1 to the first page buffer circuit PB1, the control logic circuit 121 may simultaneously provide the second latch control signals CTR2 to the second page buffer circuit PB2.

In a third operation ③, the control logic circuit 121 may provide third latch control signals CTR3 to the first page buffer circuit PB1. For example, during a second sequence following the first sequence, to perform the second program operation based on the first verification information VI1 indicating that the first program operation has passed, the control logic circuit 121 may provide the third latch control signals CTR3 to the first page buffer circuit PB1.

In a fourth operation ④, the control logic circuit 121 may provide fourth latch control signals CTR4 to the second page buffer circuit PB2. For example, during the second sequence, to again perform the first program operation based on the second verification information VI2 indicating the fail, the control logic circuit 121 may provide the fourth latch control signals CTR4 to the second page buffer circuit PB2. That is, the control logic circuit 121 may provide different latch control signals (e.g., the third and fourth latch control signals CTR3 and CTR4) to allow the first page buffer circuit PB1 and the second page buffer circuit PB2 to perform different program operations.

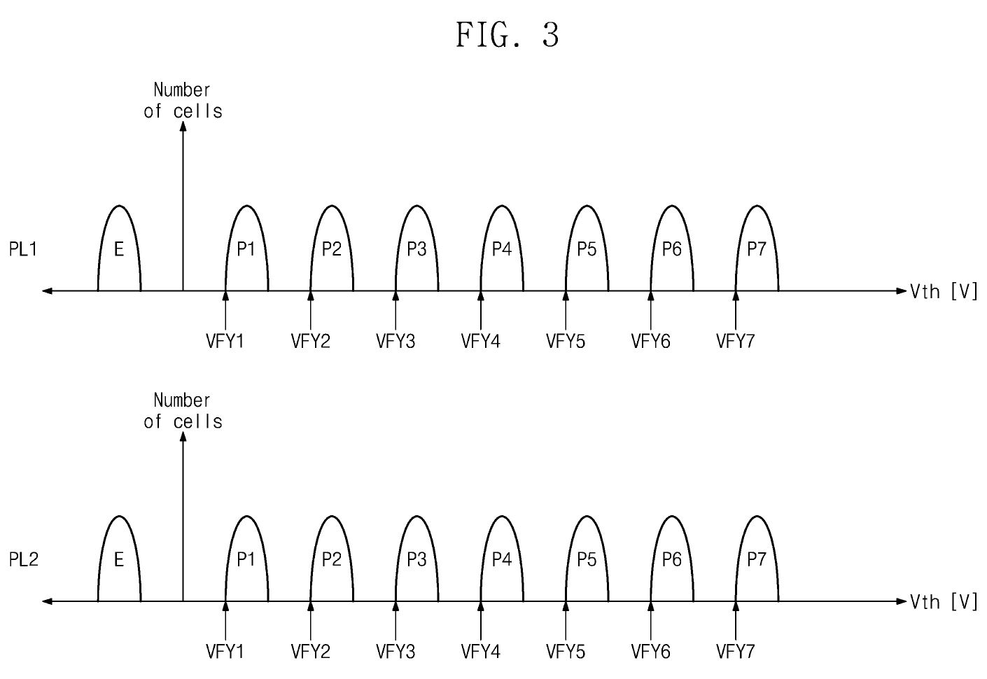

FIG. 3 is a distribution diagram for describing a program operation of a non-volatile memory device according to some embodiments of the present disclosure. Referring to FIGS. 2 and 3, the program operations may be respectively performed in the first memory plane circuit PL1 and the second memory plane circuit PL2 of the non-volatile memory device 120. Distributions of FIG. 3 are distributions of the first memory plane circuit PL1 and the second memory plane circuit PL2. In the distribution diagram of FIG. 3, the horizontal axis represents a threshold voltage of a memory cell, and the vertical axis represents the number of memory cells.

The non-volatile memory device 120 may store or program data in a plurality of memory cells by changing threshold voltages of the plurality of memory cells in the memory cell array 122. For example, based on data to be stored, the non-volatile memory device 120 may perform the program operations on the first memory plane circuit PL1 and the second memory plane circuit PL2 such that each memory cell of an erase state “E” has at least one of first, second, third, fourth, fifth, sixth, or seventh program states P1, P2, P3, P4, P5, P6, or P7. In some embodiments, the program operations may be performed in units of word line or page.

The first, second, third, fourth, fifth, sixth, or seventh program states P1, P2, P3, P4, P5, P6, or P7 are provided for better understanding of the program operation according to the present disclosure and are not intended to limit the scope of the present disclosure. The plurality of memory cells of the non-volatile memory device 120 may have program states, the number of which is more than or less than the number of first, second, third, fourth, fifth, sixth, or seventh program states P1, P2, P3, P4, P5, P6, or P7.

In some embodiments, the non-volatile memory device 120 may perform the program operations on the plurality of memory cells such that each memory cell of the erase state “E” has at least one of the first, second, third, fourth, fifth, sixth, or seventh program states P1, P2, P3, P4, P5, P6, or P7. In the program operation, first, second, third, fourth, fifth, sixth, or seventh verify voltages VFY1, VFY2, VFY3, VFY4, VFY5, VFY6, or VFY7 may be used. For example, memory cells on which the program operation is performed to have the seventh program state P7 are programed to have threshold voltages higher than the seventh verify voltage VFY7. The first, second, third, fourth, fifth, or sixth program states P1, P2, P3, P4, P5, or P6 are similar to the seventh program state P7, and thus, additional description will be omitted to avoid redundancy.

In some embodiments, the program operations on the first memory plane circuit PL1 and the second memory plane circuit PL2 may be sequentially performed. For example, the program operations on the first memory plane circuit PL1 and the second memory plane circuit PL2 may be sequentially performed such that the first memory plane circuit PL1 and the second memory plane circuit PL2 sequentially have the first, second, third, fourth, fifth, sixth, or seventh program states P1, P2, P3, P4, P5, P6, or P7.

In some embodiments, the first memory plane circuit PL1 and the second memory plane circuit PL2 may have different program states. For example, during an arbitrary sequence, the first memory plane circuit PL1 may have the third program state P3, and the second memory plane circuit PL2 may have the first program state P1. Because the first memory plane circuit PL1 and the second memory plane circuit PL2 have different distributions or different threshold voltage, the first memory plane circuit PL1 and the second memory plane circuit PL2 may have different program states.

In some embodiments, the control logic circuit 121 of FIG. 2 may provide different latch control signals to the first page buffer circuit PB1 and the second page buffer circuit PB2 respectively connected to the first memory plane circuit PL1 and the second memory plane circuit PL2, which have different program states. For example, the control logic circuit 121 of FIG. 2 may provide the third latch control signals CTR3 to the first page buffer circuit PB1 to perform the program operation for the fourth program state P4 and may provide the fourth latch control signals CTR4 to the second page buffer circuit PB2 to perform the program operation for the second program state P2.

In some embodiments, all the program operations on the first memory plane circuit PL1 may be completed, but some program operations on the second memory plane circuit PL2 may be not completed. For example, during an arbitrary sequence, the first memory plane circuit PL1 may have the seventh program state P7, but the second memory plane circuit PL2 may have a program state (e.g., the sixth program state P6) which is not the seventh program state P7. As the control logic circuit 121 of FIG. 2 provides a latch control signal indicating an idle state to the first page buffer circuit PB1, unnecessary power consumption may be prevented, and power efficiency may be improved.

FIG. 4 is a diagram describing a page buffer circuit according to some embodiments of the present disclosure. Referring to FIG. 4, the first page buffer circuit PB1 may include a plurality of latches. The first page buffer circuit PB1 may include a first sense latch SL1, a first force latch FL1, a first upper bit latch ML1, a first lower bit latch LL1, and a first cache latch CL1.

The first sense latch SL1, the first force latch FL1, the first upper bit latch ML1, the first lower bit latch LL1, and the first cache latch CL1 described above are provided for better understanding of a plurality of latches which the first page buffer circuit PB1 of the present disclosure includes and are not intended to limit the scope of the present disclosure. The first page buffer circuit PB1 of the present disclosure may include various types of latches including some or at least some of the above latches.

Referring to FIGS. 2 and 4, the first sense latch SL1 may sense data stored in a memory cell of the first memory plane circuit PL1 or a threshold voltage of a memory cell of the first memory plane circuit PL1 and may store the sensed result. In the program operation, the first sense latch SL1 may apply a voltage to the first bit line BL1.

In the program operation, the first force latch FL1 may improve a program threshold voltage distribution. For example, the first force latch FL1 may change a value of the stored data based on the threshold voltage of the memory cell in the first memory plane circuit PL1 during the program operation and may apply a voltage of the first bit line BL1 based on the value of the stored data.

In the program operation, the first upper bit latch ML1, the first lower bit latch LL1, and the first cache latch CL1 may store the data “DATA” received through the I/O circuit 123. In the read operation, the first upper bit latch ML1, the first lower bit latch LL1, and the first cache latch CL1 may be provided with the data read from the memory cell of the first memory plane circuit PL1 from the first sense latch SL1 and may output the provided data to the outside (e.g., the storage controller 110) through the I/O circuit 123.

As described above, the plurality of latches may store data or bits or may output data or bits to the outside (e.g., the storage controller 110 or the memory cell array 122), and may provide data or bits to any other latches. Each of the above operations of the plurality of latches may be referred to as a “dump operation”.

The first sense latch SL1, the first force latch FL1, the first upper bit latch ML1, the first lower bit latch LL1, and the first cache latch CL1 may perform the dump operations based on the first latch control signals CTR1. The first latch control signals CTR1 may include at least some of a first sense latch control signal CTR1_S, a first force latch control signal CTR1_F, a first upper bit latch control signal CTR1_M, a first lower bit latch control signal CTR1_L, and a first cache latch control signal CTR1_C.

The first sense latch SL1, the first force latch FL1, the first upper bit latch ML1, the first lower bit latch LL1, and the first cache latch CL1 may perform the dump operations based on the corresponding signals among the first latch control signals CTR1. The first latch control signals CTR1 may control the plurality of latches sequentially or in parallel. The plurality of latches may perform the dump operations sequentially or in parallel based on the first latch control signals CTR1. That is, to perform the program operation of the first memory plane circuit PL1 or to verify the program operation, the plurality of latches may perform the dump operations based on the first latch control signals CTR1.

Because the second page buffer circuit PB2 of FIG. 2 is similar to the first page buffer circuit PB1, the detailed description associated with a plurality of latches included in the second page buffer circuit PB2 and the second and fourth latch control signals CTR2 and CTR4 controlling the plurality of latches are omitted.

FIG. 5 is a block diagram of a non-volatile memory device according to some embodiments of the present disclosure. Referring to FIG. 5, a non-volatile memory device 220 may include a control logic circuit 221, a memory cell array 222, an I/O circuit 223, the first page buffer circuit PB1, and the second page buffer circuit PB2. The non-volatile memory device 220 is similar to the non-volatile memory device 120 of FIG. 2, and thus, additional description be omitted to be will be omitted to avoid redundancy.

The control logic circuit 221 may include a latch controller 221-1, a plane select circuit 221-2, and a time management circuit 221-3. The latch controller 221-1 may generate latch control signals (e.g., the first, second, third, and fourth latch control signals CTR1, CTR2, CTR3, andCTR4). For example, the latch controller 221-1 may generate the latch control signals (e.g., the first, second, third and fourth latch control signals CTR1, CTR2, CTR3, andCTR4) for controlling a plurality of first latches of the first page buffer circuit PB1 and a plurality of second latches of the second page buffer circuit PB2.

In some embodiments, the latch controller 221-1 may generate latch control signals (e.g., the third and fourth latch control signals CTR3 and CTR4) based on a program state and verification information of the first memory plane circuit PL1 and the second memory plane circuit PL2 and a plane selection signal. The plane selection signal may be generated and provided by the plane select circuit 221-2.

In some embodiments, the latch controller 222-1 may provide the latch control signals to the first page buffer circuit PB1 and the second page buffer circuit PB2. For example, the latch controller 221-1 may verify the program operations of the first memory plane circuit PL1 and the second memory plane circuit PL2 and may provide the latch control signals (e.g., the first, second, third, and fourth latch control signals CTR1, CTR2, CTR3, and CTR4) for the same or different program operations to the first latches of the first page buffer circuit PB1 and the second latches of the second page buffer circuit PB2 based on verification information being the verified results.

The plane select circuit 221-2 may generate the plane selection signal. For example, the plane select circuit 221-2 may generate the plane selection signal indicating whether to generate latch control signals for controlling a page buffer circuit connected to any memory plane circuit among memory plane circuits (e.g., the first and second memory plane circuits PL1 and PL2) in the memory cell array 222. The plane select circuit 221-2 may generate the plane selection signal indicating the memory plane circuits (e.g., the first and second memory plane circuits PL1 and PL2) in the memory cell array 222 based on a clock signal or periodically.

The time management circuit 221-3 may generate a timing signal. For example, the time management circuit 221-3 may generate the timing signal for generating the latch control signals (e.g., the first, second, third and fourth latch control signals CTR1, CTR2, CTR3, and CTR4) during a sequence. In some embodiments, the time management circuit 221-3 may generate the timing signal based on the clock signal.

In the present disclosure, the latch controller 221-1, the plane select circuit 221-2, and the time management circuit 221-3 are illustrated as an example as being separate components, but at least some of the latch controller 221-1, the plane select circuit 221-2, and the time management circuit 221-3 may operate as one component.

The first page buffer circuit PB1 may include the first latches, and the second page buffer circuit PB2 may include the second latches. Referring to FIGS. 4 and 5, the first latches may include the first sense latch SL1, the first force latch FL1, the first upper bit latch ML1, the first lower bit latch LL1, and the first cache latch CL1. As in the first latches, the second latches may include a second sense latch, a second force latch, a second upper bit latch, a second lower bit latch, and a second cache latch.

The first page buffer circuit PB1 (or the first latches) and the second page buffer circuit PB2 (or the second latches) may perform the dump operations under control of the control logic circuit 221. For example, the first page buffer circuit PB1 (or the first latches) may perform the dump operations based on the first and third latch control signals CTR1 and CTR3, and the second page buffer circuit PB2 (or the second latches) may perform the dump operations based on the second and fourth latch control signals CTR2 and CTR4. The dump operations which the first page buffer circuit PB1 (or the first latches) and the second page buffer circuit PB2 (or the second latches) perform may be different from each other.

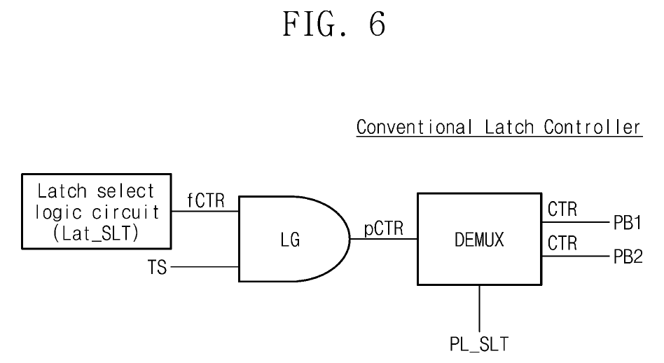

FIG. 6 is a diagram describing a conventional latch controller. Referring to FIG. 6, a conventional latch controller may include a latch select logic circuit Lat_SLT, a logic gate LG, and a de-multiplexer DEMUX. The latch select logic circuit Lat_SLT may select a latch targeted for control from among a plurality of latches in a page buffer circuit and may generate an original latch control signal fCTR for controlling the selected latch.

The logic gate LG may generate a pre-latch control signal pCTR based on the original latch control signal fCTR and a timing signal TS.

The de-multiplexer DEMUX may provide the pre-latch control signal pCTR as the latch control signal CTR to the first and second page buffer circuits PB1 and PB2 based on a plane selection signal PL_SLT.

The conventional latch controller may provide the same latch control signals CTR to page buffer circuits (e.g., the first and second page buffer circuits PB1 and PB2). Accordingly, when some of memory plane circuits connected to the page buffer circuits have a program fail state, all the memory plane circuits should again perform the same program operations. That is, the remaining memory plane circuits having a program pass state should again perform the program operations unnecessarily. To solve the above issue, there may be a need to provide different latch control signals to different page buffer circuits.

FIG. 7 is a diagram describing a latch controller according to some embodiments of the present disclosure. Referring to FIGS. 5 and 7, the latch controller 221-1 may include a latch select logic circuit Lat_SLT, a first logic gate LG1, and a second logic gate LG2. The latch select logic circuit Lat_SLT may generate pre-latch control signals (e.g., first and second pre-latch control signals pCTR1 and pCTR2). For example, the latch select logic circuit Lat_SLT may generate the pre-latch control signals (e.g., first and second pre-latch control signals pCTR1 and pCTR2) based on verification information (e.g., the first and second verification information VI1 and VI2) and the plane selection signal PL_SLT.

The first and second verification information VI1 and VI2 described above are provided for better understanding of the latch select logic circuit Lat_SLT according to the present disclosure and are not intended to limit the scope of the present disclosure. The latch select logic circuit Lat_SLT may generate the pre-latch control signals (e.g., the first and second pre-latch control signals pCTR1 and pCTR2) based on any other information (e.g., program states of memory plane circuits connected to page buffer circuits), in addition to the first and second verification information VI1 and VI2.

The latch select logic circuit Lat_SLT may generate pre-latch control signals for controlling page buffer circuits respectively connected to a plurality of memory planes (e.g., the first and second memory plane circuits PL1 and PL2) based on the plane selection signal PL_SLT. The latch select logic circuit Lat_SLT may provide the generated pre-latch control signals (e.g., the first and second pre-latch control signals pCTR1 and pCTR2) to logic gates (e.g., the first and second logic gates LG1 and LG2) respectively connected to corresponding page buffer circuits (e.g., the first and second page buffer circuits PB1 and PB2).

the first logic gate LG1 may generate the first latch control signals CTR1 based on the first pre-latch control signal pCTR1 and the timing signal TS. The first latch control signals CTR1 may include at least some of the first sense latch control signal CTR1_S, the first force latch control signal CTR1_F, the first upper bit latch control signal CTR1_M, the first lower bit latch control signal CTR1_L, and the first cache latch control signal CTR1_C. The first logic gate LG1 may provide the first latch control signals CTR1 to the first page buffer circuit PB1.

The second logic gate LG2 may generate the second latch control signals CTR2 based on the second pre-latch control signal pCTR2 and the timing signal TS. The second latch control signals CTR2 may include at least some of the second sense latch control signal CTR2_S, the second force latch control signal CTR2_F, the second upper bit latch control signal CTR2_M, the second lower bit latch control signal CTR2_L, and the second cache latch control signal CTR2_C. The second logic gate LG2 may provide the second latch control signals CTR2 to the second page buffer circuit PB2.

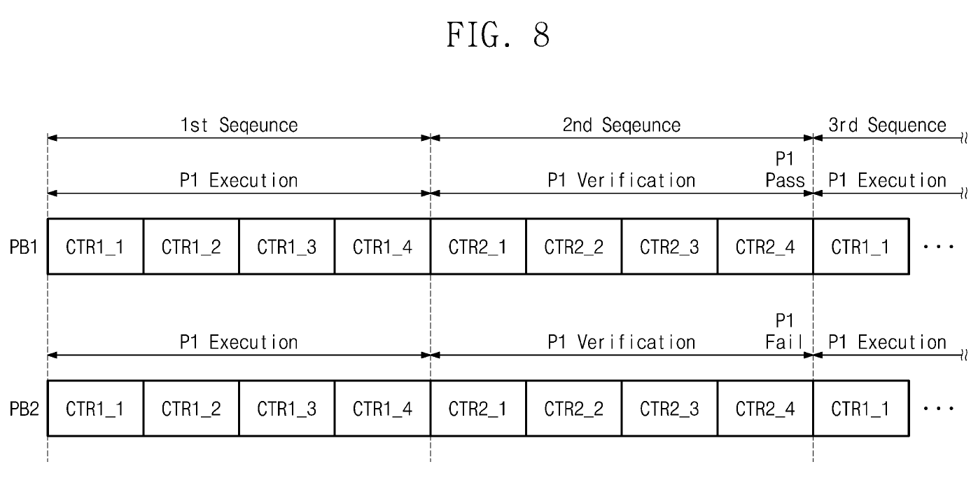

FIG. 8 is a timing diagram describing latch control signals which a conventional control logic circuit generates. Referring to FIGS. 6 and 8, during a plurality of sequential sequences, a plurality of latch control signals may be provided to the first and second page buffer circuits PB1 and PB2. The conventional control logic circuit or the conventional latch controller may provide the plurality of latch control signals to the first and second page buffer circuits PB1 and PB2. For example, the conventional control logic circuit may provide first latch control signals CTR1_1, CTR1_2, CTR1_3, and CTR1_4 to the first and second page buffer circuits PB1 and PB2 during a first sequence, may provide second latch control signals CTR2_1, CTR2_2, CTR2_3, and CTR2_4 to the first and second page buffer circuits PB1 and PB2 during a second sequence, and may provide first latch control signals CTR1_1, CTR1_2, CTR1_3, and CTR1_4 to the first and second page buffer circuits PB1 and PB2 during a third sequence.

During the first sequence, the conventional control logic circuit may provide the first latch control signals CTR1_1, CTR1_2, CTR1_3, and CTR1_4 to the first and second page buffer circuits PB1 and PB2 to perform the first program operation. During a second sequence following the first sequence, the conventional control logic circuit may provide the second latch control signals CTR2_1, CTR1_2, CTR1_3, and CTR2_4 to the first and second page buffer circuits PB1 and PB2 to verify the first program operation. In this case, a first memory plane circuit connected to the first page buffer circuit PB1 may have a first program pass state, and a second memory plane circuit connected to the second page buffer circuit PB2 may have a first program fail state.

During a third sequence following the second sequence, the conventional control logic circuit may provide the first latch control signals CTR1_1, CTR1_2, CTR1_3, and CTR1_4 to the first and second page buffer circuits PB1 and PB2 to again perform the first program operation. That is, when some of the first and second memory plane circuits have the first program fail state, the conventional control logic circuit should iterate the same program operations in all the page buffer circuits.

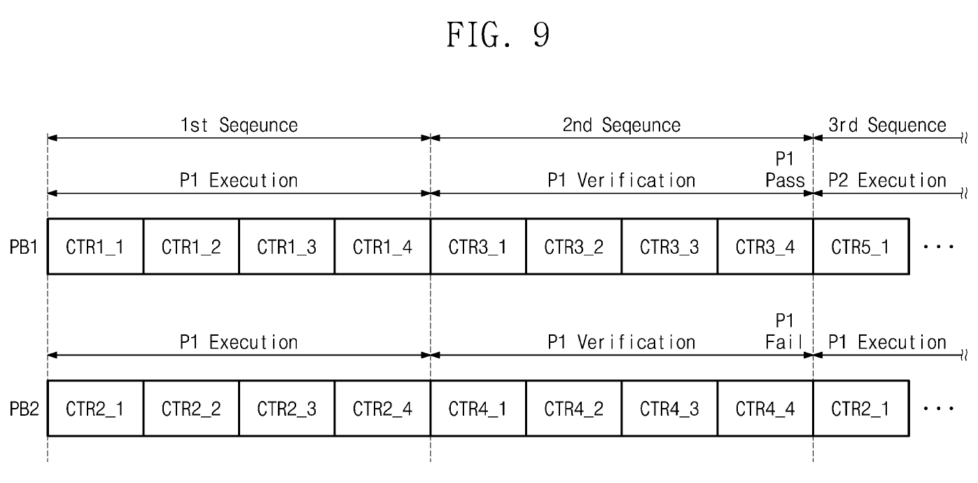

FIG. 9 is a timing diagram describing latch control signals which a control logic circuit according to some embodiments of the present disclosure generates. Referring to FIGS. 3, 5, and 9, the control logic circuit 221 may provide latch control signals (e.g., first, second, third, fourth, and fifth latch control signals CTR1, CTR2, CTR3, CTR4, and CTR5) to the first and second page buffer circuits PB1 and PB2.

For example, during the first to third sequences, the control logic circuit 221 may provide first latch control signals CTR1_1, CTR1_2, CTR1_3, and CTR1_4, third latch control signals CTR3_1, CTR3_2, CTR3_3, and CTR3_4, and fifth latch control signals CTR5_1, CTR5_2, CTR5_3, CTR5_4, and CTR5_4 to the first page buffer circuit PB1 and may provide second latch control signals CTR2_1, CTR2_2, CTR2_3, and CTR2_4 and fourth latch control signals CTR4_1, CTR4_2, CTR4_3, and CTR4_4 to the second page buffer circuit PB2.

The above latch control signals are provided for better understanding of the control logic circuit 221 according to the present disclosure and are not intended to limit the scope of the present disclosure. The latch control signals may include signals, the number of which is less than four or more than four. The latch control signals may include signals which allow the latches to perform the dump operations necessary to verify the program operation during the program operation.

The control logic circuit 221 may provide different latch control signals to the first and second page buffer circuits PB1 and PB2 during one sequence (e.g., the first sequence, the second sequence, and the third sequence).

During the first sequence, the control logic circuit 221 may provide the first latch control signals CTR1_1, CTR1_2, CTR1_3, and CTR1_4 to the first page buffer circuit PB1 such that the first memory plane circuit PL1 performs the first program operation. Simultaneously, for the second memory plane circuit PL2 to perform the first program operation, the control logic circuit 221 may provide the second latch control signals CTR2_1, CTR2_2, CTR2_3, and CTR2_4 to the second page buffer circuit PB2. The first latch control signals CTR1_1, CTR1_2, CTR1_3, and CTR1_4 and the second latch control signals CTR2_1, CTR2_2, CTR2_3, and CTR2_4 may be identical to or different from each other.

During the first sequence, the first latches of the first page buffer circuit PB1 may sequentially perform the dump operations based on the first latch control signals CTR1_1, CTR1_2, CTR1_3, and CTR1_4, and the second latches of the second page buffer circuit PB2 may sequentially perform the dump operations based on the second latch control signals CTR2_1, CTR2_2, CTR2_3, and CTR2_4.

During the second sequence, the control logic circuit 221 may provide the third latch control signals CTR3_1, CTR3_2, CTR3_3, and CTR3_4 to the first page buffer circuit PB1 to verify the first program operation of the first memory plane circuit PL1. Simultaneously, the control logic circuit 221 may provide the fourth latch control signals CTR4_1, CTR4_2, CTR4_3, and CTR4_4 to the second page buffer circuit PB2 to verify the first program operation of the second memory plane circuit PL2.

During the second sequence, the first latches of the first page buffer circuit PB1 may sequentially perform the dump operations based on the third latch control signals CTR3_1, CTR3_2, CTR3_3, and CTR3_4, and the second latches of the second page buffer circuit PB2 may sequentially perform the dump operations based on the fourth latch control signals CTR4_1, CTR4_2, CTR4_3, and CTR4_4. The control logic circuit 221 may determine whether the first and second memory plane circuits PL1 and PL2 have the first program pass state or the first program fail state, based on an execution result of the dump operation of each of the first and second latches.

In some embodiments, when the first memory plane circuit PL1 has the first program pass state and the second memory plane circuit PL2 has the first program fail state, there may be a need for the second memory plane circuit PL2 to again perform the first program operation. Accordingly, for the second memory plane circuit PL2 to perform the first program operation, the control logic circuit 221 may again provide the second latch control signals CTR2_1, CTR2_2, CTR2_3, and CTR2_4 to the second page buffer circuit PB2.

However, because the first memory plane circuit PL1 has the first program pass state, the control logic circuit 221 may again provide the fifth latch control signals CTR5_1, CTR5_2, CTR5_3, and CTR5_4 to the first page buffer circuit PB1 such that the first memory plane circuit PL1 performs the second program operation.

That is, the control logic circuit 221 may provide different latch control signals to the first page buffer circuit PB1 and the second page buffer circuit PB2 during at least one sequence, based on the program states of the first memory plane circuit PL1 and the second memory plane circuit PL2.

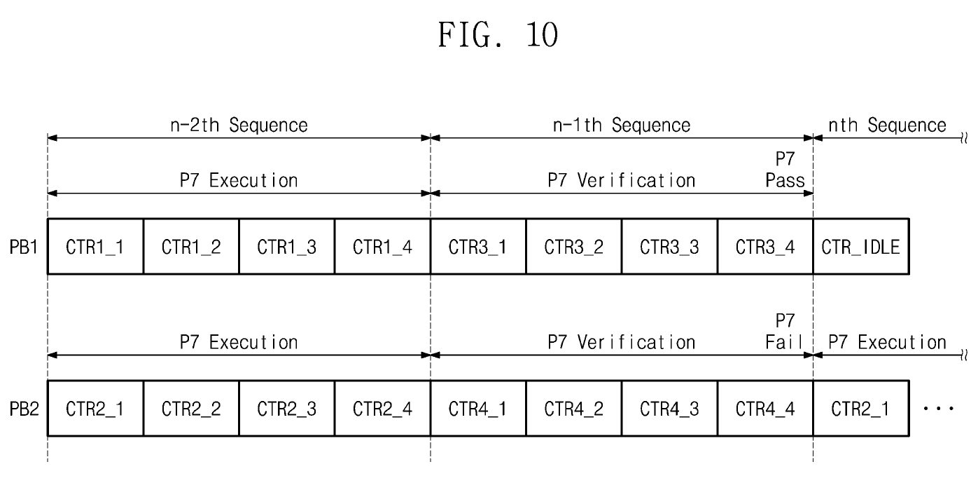

FIG. 10 is a timing diagram describing latch control signals which a control logic circuit according to some embodiments of the present disclosure generates. Referring to FIGS. 3, 5, and 10, the control logic circuit 221 may provide latch control signals (e.g., the first, second, third, and fourth latch control signals CTR1, CTR2, CTR3, and CTR4) and latch control signals CTR_IDLE indicating the idle state to the first and second page buffer circuits PB1 and PB2.

The control logic circuit 221 of may provide the latch control signals CTR_IDLE indicating the idle state to page buffer circuits (e.g., the first and second page buffer circuit PB1 and PB2). For example, when there is a need for the first and second memory plane circuits PL1 and PL2 to perform first, second, third, fourth, fifth, sixth, and seventh program operations, the control logic circuit 221 may provide a latch control signal indicating the idle state to a page buffer circuit connected to a memory plane circuit, in which the execution of the first, second, third, fourth, fifth, sixth, and seventh program operations is completed, from among the first and second memory plane circuits PL1 and PL2.

As the latch control signals CTR_IDLE indicating the idle state is provided to page buffer circuits, the control logic circuit 221 may prevent unnecessary power consumption due to the dump operations of latches and may improve power efficiency.

During an (n-2)-th sequence, the control logic circuit 221 may respectively provide the first and second latch control signals CTR1 and CTR2 to the first and second page buffer circuits PB1 and PB2 such that the first and second memory plane circuits PL1 and PL2 performs the seventh program operations. The first and second latch control signals CTR1 and CTR2 may be different from the first and second latch control signals CTR1 and CTR2 of FIG. 9. Herein, “n” is an arbitrary natural number more than two.

During the (n-2)-th sequence, the first latches of the first page buffer circuit PB1 may sequentially perform the dump operations based on the first latch control signals CTR1_1, CTR1_2, CTR1_3, and CTR1_4, and the second latches of the second page buffer circuit PB2 may sequentially perform the dump operations based on the second latch control signals CTR2_1, CTR2_2, CTR2_3, and CTR2_4.

During an (n-1)-th sequence, the control logic circuit 221 may provide the third latch control signals CTR3_1, CTR3_2, CTR3_3, and CTR3_4 to the first page buffer circuit PB1 to verify the seventh program operation of the first memory plane circuit PL1. Simultaneously, the control logic circuit 221 may provide the fourth latch control signals CTR4_1, CTR4_2, CTR4_3, and CTR4_4 to the second page buffer circuit PB2 to verify the seventh program operation of the second memory plane circuit PL2.

During the (n-2)-th sequence, the first latches of the first page buffer circuit PB1 may sequentially perform the dump operations based on the third latch control signals CTR3_1, CTR3_2, CTR3_3, and CTR3_4, and the second latches of the second page buffer circuit PB2 may sequentially perform the dump operations based on the fourth latch control signals CTR4_1, CTR4_2, CTR4_3, and CTR4_4. The control logic circuit 221 may determine whether the first and second memory plane circuits PL1 and PL2 have the first program pass state or the first program fail state, based on an execution result of the dump operation of each of the first and second latches.

In some embodiments, when the first memory plane circuit PL1 has the seventh program pass state and the second memory plane circuit PL2 has the seventh program fail state, there may be a need for the second memory plane circuit PL2 to again perform the seventh program operation. Accordingly, for the second memory plane circuit PL2 to perform the seventh program operation, the control logic circuit 221 may again provide the second latch control signals CTR2_1, CTR2_2, CTR2_3, and CTR2_4 to the second page buffer circuit PB2.

However, because the first memory plane circuit PL1 has the seventh program pass state and completes all the program operations, the control logic circuit 221 may provide the latch control signals CTR_IDLE indicating the idle state to the first page buffer circuit PB1. The first latches of the first page buffer circuit PB1 may have the idle state based on the latch control signals CTR_IDLE indicating the idle state. The first latches having the idle state may not perform the dump operations, and the first latches having the idle state may not consume a power or may consume a power smaller in amount than a power consumed when performing the dump operations.

That is, the control logic circuit 221 may control the first page buffer circuit PL1 based on the program states of the first memory plane circuit PL1 and the second memory plane circuit PL2 such that the first latches connected to the first memory plane circuit PL1 in which all the program operations are completed have the idle state. Accordingly, the control logic circuit 221 may improve the power efficiency of the non-volatile memory device 220.

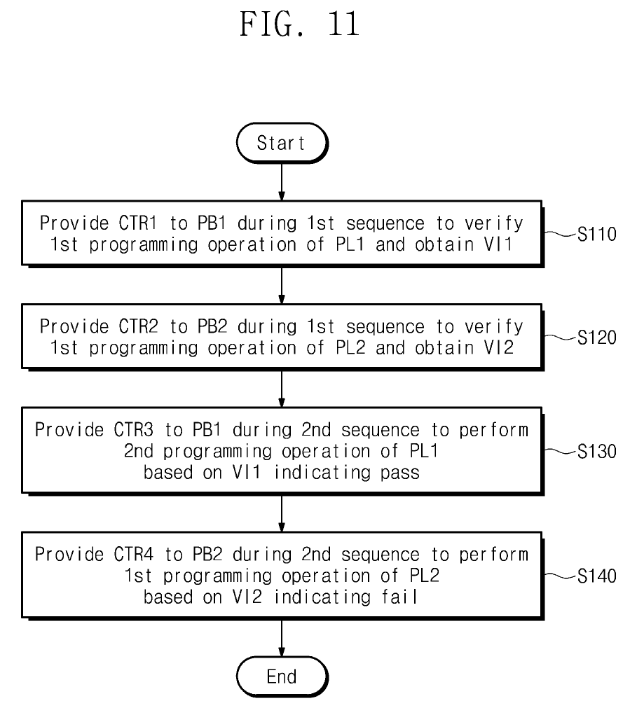

FIG. 11 is a flowchart describing an operating method of a non-volatile memory device according to some embodiments of the present disclosure. Referring to FIGS. 2 and 11, the control logic circuit 121 of the non-volatile memory device 120 may individually control the first and second page buffer circuits PB1 and PB2.

In operation S110, to verify the first program operation of the first memory plane circuit PL1 during a first sequence, the control logic circuit 121 may provide the first latch control signals CTR1 to the first page buffer circuit PB1 and may obtain or receive the first verification information VI1. For example, the control logic circuit 121 may sequentially provide the latches of the first page buffer circuit PB1 with the first latch control signals CTR1 capable of controlling the dump operations of the latches of the first page buffer circuit PB1 and may obtain or receive the first verification information VI1 depending on a result of the dump operations of the latches.

The first latch control signals CTR1 may be used to control the latches in the first memory plane circuit PL1 to verify the first program operation of the first memory plane circuit PL1.

The first verification information VI1 may indicate whether the first memory plane circuit PL1 has the first program pass state or the first program fail state, based on a result of the first program operation performed before the first sequence.

In operation S120, to verify the first program operation of the second memory plane circuit PL2 during the first sequence, the control logic circuit 121 may provide the second latch control signals CTR2 to the second page buffer circuit PB2 and may obtain or receive the second verification information VI2. For example, at the same time with operation S110 (i.e., during the first sequence), the control logic circuit 121 may sequentially provide the latches of the second page buffer circuit PB2 with the second latch control signals CTR2 capable of controlling the dump operations of the latches of the second page buffer circuit PB2 and may obtain or receive the second verification information VI2 depending on a result of the dump operations of the latches.

The second latch control signal CTR2 may be used to control the latches in the second memory plane circuit PL2 to verify the first program operation at the second memory plane circuit PL2. Also, because the second latch control signals CTR2 control the latches in the same manner to verify the same program operation with the first latch control signals CTR1, the second latch control signals CTR2 may be identical to the first latch control signals CTR1.

The second verification information VI2 may indicate whether the second memory plane circuit PL2 has the first program pass state or the first program fail state, based on a result of the first program operation performed before the first sequence.

In operation S130, during a second sequence following the first sequence, to perform the second program operation based on the first verification information VI1 indicating the pass, the control logic circuit 121 may provide the third latch control signals CTR3 to the first page buffer circuit PB1. For example, based on the first verification information VI1 indicating the pass, the control logic circuit 121 may determine that the second program operation is required and may provide the third latch control signals CTR3 to the first page buffer circuit PB1 to perform the second program operation.

In operation S140, during the second sequence, to perform the first program operation based on the second verification information VI2 indicating the fail, the control logic circuit 121 may provide the fourth latch control signals CTR4 to the second page buffer circuit PB2. For example, at the same time with operation S130 (i.e., during the second sequence), the control logic circuit 121 may determine that the first program operation is required based on the second verification information VI2 indicating the fail and may provide the fourth latch control signals CTR4 to the second page buffer circuit PB2 to again perform the first program operation.

For the second memory plane circuit PL2 to again perform the first program operation, the fourth latch control signals CTR4 which are signals controlling the second page buffer circuit PB2 to again perform the first program operation may be different from the third latch control signals CTR3. That is, the control logic circuit 121 may provide different latch control signals to the first and second page buffer circuits PB1 and PB2.

According to some embodiments of the present disclosure, a non-volatile memory device including a plurality of page buffer circuits, an operating method thereof, and a storage device including the same are provided.

Also, a non-volatile memory device which improves power efficiency by individually controlling a plurality of page buffer circuits depending on a program state such that unnecessary dump operations are removed, an operating method thereof, and a storage device including the same are provided.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A non-volatile memory device comprising:
a first memory plane circuit;
a second memory plane circuit;
a first page buffer circuit connected to the first memory plane circuit through first bit lines;
a second page buffer circuit connected to the second memory plane circuit through second bit lines; and
a control logic circuit,
wherein the control logic circuit is configured to:
during a first sequence, provide first latch control signals to the first page buffer circuit to verify a first program operation of the first memory plane circuit and receive first verification information;
during the first sequence, provide second latch control signals to the second page buffer circuit to verify the first program operation of the second memory plane circuit and receive second verification information;
during a second sequence following the first sequence, provide third latch control signals to the first page buffer circuit to perform a second program operation based on the first verification information indicating a pass state; and
during the second sequence, provide fourth latch control signals to the second page buffer circuit to perform the first program operation based on the second verification information indicating a fail state.

2. The non-volatile memory device of claim 1, wherein the first page buffer circuit includes a plurality of first latches configured to perform first dump operations and third dump operations based on the first latch control signals and the third latch control signals, and
wherein the second page buffer circuit includes a plurality of second latches configured to perform second dump operations and fourth dump operations based on the second latch control signals and the fourth latch control signals.

3. The non-volatile memory device of claim 2, wherein, during the first sequence, the control logic circuit sequentially provides the first latch control signals to the plurality of first latches and sequentially provides the second latch control signals to the plurality of second latches.

4. The non-volatile memory device of claim 2, wherein the plurality of first latches include a sense latch, a force latch, an upper bit latch, a lower bit latch, and a cache latch.

5. The non-volatile memory device of claim 1, wherein the control logic circuit is configured to generate the third latch control signals and the fourth latch control signals based on the first verification information, the second verification information, and a plane selection signal.

6. The non-volatile memory device of claim 5, wherein the control logic circuit comprises:
a latch select logic circuit configured to generate a first pre-latch control signal based on the first verification information and the plane selection signal indicating the first memory plane circuit and configured to generate a second pre-latch control signal based on the second verification information and the plane selection signal indicating the second memory plane circuit;
a first logic gate configured to generate the third latch control signals based on the first pre-latch control signal and a timing signal; and
a second logic gate configured to generate the fourth latch control signals based on the second pre-latch control signal and the timing signal.

7. The non-volatile memory device of claim 1, wherein the control logic circuit is further configured to:
during a third sequence following the second sequence, provide fifth latch control signals to the first page buffer circuit to verify the second program operation of the first memory plane circuit and receive third verification information; and
during the third sequence, provide the second latch control signals to the second page buffer circuit to verify the first program operation of the second memory plane circuit and receive fourth verification information.

8. The non-volatile memory device of claim 7, wherein the control logic circuit is further configured to:
during a fourth sequence following the third sequence, provide sixth latch control signals indicating an idle state to the first page buffer circuit based on the third verification information indicating the pass state; and
during the fourth sequence, provide seventh latch control signals to the second page buffer circuit to perform the second program operation based on the fourth verification information indicating the pass state.

9. An operating method of a non-volatile memory device which includes a first page buffer circuit connected to a first memory plane circuit, a second page buffer circuit connected to a second memory plane circuit, and a control logic circuit, the method comprising:
during a first sequence, providing, by the control logic circuit, first latch control signals to the first page buffer circuit to verify a first program operation of the first memory plane circuit and receiving first verification information;
during the first sequence, providing, by the control logic circuit, second latch control signals to the second page buffer circuit to verify the first program operation of the second memory plane circuit and receiving second verification information;
during a second sequence following the first sequence, providing, by the control logic circuit, third latch control signals to the first page buffer circuit to perform a second program operation based on the first verification information indicating a pass state; and
during the second sequence, providing, by the control logic circuit, fourth latch control signals to the second page buffer circuit to perform the first program operation based on the second verification information indicating a fail state.

10. The method of claim 9, wherein the first page buffer circuit includes a plurality of first latches configured to perform first dump operations based on the first latch control signals and the third latch control signals, and
wherein the second page buffer circuit includes a plurality of second latches configured to perform second dump operations based on the second latch control signals and the fourth latch control signals.

11. The method of claim 10, wherein the providing the first latch control signals to the first page buffer circuit to verify the first program operation of the first memory plane circuit and the receiving first verification information, by the control logic circuit, during the first sequence comprises:
during the first sequence, sequentially providing, by the control logic circuit, the first latch control signals to the plurality of first latches, and
wherein the providing the second latch control signals to the second page buffer circuit to verify the first program operation of the second memory plane circuit and the receiving the second verification information, by the control logic circuit, during the first sequence comprises:
during the first sequence, sequentially providing, by the control logic circuit, the second latch control signals to the plurality of second latches.

12. The method of claim 10, wherein the plurality of first latches include a sense latch, a force latch, an upper bit latch, a lower bit latch, and a cache latch.

13. The method of claim 9, wherein the control logic circuit is configured to generate the third latch control signals and the fourth latch control signals based on the first verification information, the second verification information, and a plane selection signal.

14. The method of claim 13, wherein the providing of the third latch control signals to the first page buffer circuit by the control logic circuit comprises:
generating, by the control logic circuit, a first pre-latch control signal based on the first verification information and the plane selection signal indicating the first memory plane circuit; and
generating, by the control logic circuit, the third latch control signals based on the first pre-latch control signal and a timing signal and providing the third latch control signals to the first page buffer circuit, and
wherein the providing the fourth latch control signals to the second page buffer circuit by the control logic circuit comprises:
generating, by the control logic circuit, a second pre-latch control signal based on the second verification information and the plane selection signal indicating the second memory plane circuit; and
generating, by the control logic circuit, the fourth latch control signals based on the second pre-latch control signal and the timing signal and providing the fourth latch control signals to the second page buffer circuit.

15. The method of claim 9, further comprising:
during a third sequence following the second sequence, providing, by the control logic circuit, fifth latch control signals to the first page buffer circuit to verify the second program operation of the first memory plane circuit and receiving third verification information; and
during the third sequence, providing, by the control logic circuit, the second latch control signals to the second page buffer circuit to verify the first program operation of the second memory plane circuit and receiving fourth verification information.

16. The method of claim 15, further comprising:
during a fourth sequence following the third sequence, providing, by the control logic circuit, sixth latch control signals indicating an idle state to the first page buffer circuit based on the third verification information indicating the pass state; and
during the fourth sequence, providing seventh latch control signals to the second page buffer circuit to perform the second program operation based on the fourth verification information indicating the pass state.

17. A storage device comprising:
a non-volatile memory device; and
a storage controller configured to control the non-volatile memory device,
wherein the non-volatile memory device comprises:
a first memory plane circuit;
a second memory plane circuit;
a first page buffer circuit connected to the first memory plane circuit through first bit lines;
a second page buffer circuit connected to the second memory plane circuit through second bit lines; and
a control logic circuit, and
wherein the control logic circuit is configured to:
during a first sequence, provide first latch control signals to the first page buffer circuit to verify a first program operation of the first memory plane circuit and receive first verification information;
during the first sequence, provide second latch control signals to the second page buffer circuit to verify the first program operation of the second memory plane circuit and receive second verification information;
during a second sequence following the first sequence, provide third latch control signals to the first page buffer circuit to perform a second program operation based on the first verification information indicating a pass state; and
during the second sequence, provide fourth latch control signals to the second page buffer circuit to perform the first program operation based on the second verification information indicating a fail state.

18. The storage device of claim 17, wherein the first page buffer circuit includes a plurality of first latches performing first dump operations and third dump operations based on the first latch control signals and the third latch control signals, and
wherein the second page buffer circuit includes a plurality of second latches configured to perform second dump operations and fourth dump operations based on the second latch control signals and the fourth latch control signals.

19. The storage device of claim 17, wherein the control logic circuit comprises:
a latch select logic circuit configured to generate a first pre-latch control signal based on the first verification information and a plane selection signal indicating the first memory plane circuit and configured to generate a second pre-latch control signal based on the second verification information and the plane selection signal indicating the second memory plane circuit;
a first logic gate configured to generate the third latch control signals based on the first pre-latch control signal and a timing signal; and
a second logic gate configured to generate the fourth latch control signals based on the second pre-latch control signal and the timing signal.

20. The storage device of claim 17, wherein the control logic circuit is further configured to:
during a third sequence following the second sequence, provide fifth latch control signals to the first page buffer circuit to verify the second program operation of the first memory plane circuit and receive third verification information; and
during the third sequence, provide the second latch control signals to the second page buffer circuit to verify the first program operation of the second memory plane circuit and receive fourth verification information.
